(19) United States
(12) Patent Application Publication
(10) Pub. No.: US 2008/0291625 A1
(43) Pub. Date: Nov. 27, 2008

(54) DIRECT COOLING SYSTEM

(76) Inventors: Dale Rathbun, II, Monroe, MI (US); Christopher Charles Detering, Ann Arbor, MI (US); Conley Miller, Wyandotte, MI (US)

Correspondence Address: RAMAN N. DEWAN;JACKSON WALKER, L.L.P., 100 CONGRESS AVENUE, SUITE 1100, AUSTIN, TX, 78701, US

(21) Appl. No.: 11/751,390

(22) Filed: May 21, 2007

(51) Int. Cl. H05K 7/20

(52) U.S. Cl. 361/695

(57) ABSTRACT

A direct cooling system is used for cooling one or more heat sources, such as electronic components within an enclosure. A supply air duct is coupled to an existing HVAC register and directed to the enclosure. A vented duct within the enclosure is coupled to the supply air duct and carries cool air directly to the vicinity or vicinities of the one or more heat sources. Vented ducts may be flexible and may contain provisions for future coupling of additional vented ducts for cooling additional heat sources within the enclosure.

### BACKGROUND

1. Field of the Disclosure

The present disclosure relates to equipment cooling systems, and more particularly to direct cooling of heat sources within an enclosure.

2. Description of Related Art

Heat-producing electrical equipment is often stored in enclosures. Generally, heat must be controlled within such enclosures to prevent equipment damage. To prevent overheating, various cooling schemes can be employed. For example, fans can be used to direct hot air from inside the enclosure to outside the enclosure. Unfortunately, in many cases, cooling systems are not designed to efficiently moderate temperatures of extra-sensitive equipment within an enclosure. Further, many systems do not take into account that certain components are relatively high-heat producers, requiring more cooling than other elements within an enclosure.

### BRIEF DESCRIPTION OF THE DRAWINGS

FIG. 1 depicts an embodiment of a directly cooled system including first and second vents directed at first and second high-heat sources.

FIG. 2 illustrates an adjustable vent for use in some embodied direct cooling systems.

FIG. 3. depicts an embodiment of a cooling system utilizing a closed-loop control scheme and electric fan.

FIG. 4 illustrates an embodiment of a cooling system with a plenum feeding an additional supply duct with an additional vent.

FIG. 5 depicts representative flow diagram blocks of an embodied direct cooling method.

FIG. 6 depicts an embodiment of a cooling system with ducts adapted for interchangeably installing additional ducts for system expansion.

### DESCRIPTION OF EMBODIMENT(S)

A direct cooling system is needed to deliver cool air to extra-sensitive or high-heat producing equipment within an enclosure. Optimally, a direct cooling system may employ modular components that easily can be added to for cooling of future, additional heat sources within an enclosure. Still more optimally, a direct cooling system may use various combinations of electric fans, variable vents, automatic controllers, and diffusers for achieving efficient cooling of heat sources within an enclosure.

In an embodiment, a directly cooled system is for use with a first supply duct. The first supply duct includes an inlet and an outlet. The first supply duct inlet is connectable to an existing heating, ventilation, and air conditioning (HVAC) register. The first supply duct outlet is connectable to a first duct inlet through an electronic equipment housing. The first duct has an outlet and a first air output vent. The first air output vent is positioned to direct airflow to a first heat source. The first air output vent and the first heat source are both installed or positioned within the electronic equipment housing. The directly cooled system may include a second duct which has an inlet and a second air output vent. The second duct inlet is coupled to the first duct outlet. The second air output vent is positioned to direct second airflow to a second heat source.

In another embodiment, a method of enabling direct cooling of a plurality of electronic components involves directing cooled air from an HVAC system through a first supply duct. The first supply duct is routed from an HVAC register to a first enclosure. The first enclosure is for housing a first portion of the electronic components. The method includes enabling a first vented duct within the enclosure to direct a first portion of the cooled air from a first vented duct. The first vented duct is within the first enclosure and includes a first vent for directing a first fraction of the first portion of cold air to a first electronic component. In additional embodiments, the method may further include enabling a second vented duct within the enclosure to direct a second portion of the cooled air from a second vented duct. The second vented duct includes a second vent for directing a second fraction of the first portion of the cooled air to a second electronic component.

Still another embodiment is a cooling system for retrofitting to an existing HVAC system. The HVAC system includes an HVAC supply duct, an HVAC register, and a plenum coupled to the HVAC register. The plenum has at least two openings. The cooling system includes a first flexible duct having an inlet and outlet. The first flexible duct inlet is coupled to one of the plenum's openings, and the first flexible duct outlet is connected through an enclosure's first opening to a first vented duct. The first vented duct has a first vent positioned proximate to a heat source so that cooled air from the HVAC system is directed to the first heat source. The cooling system includes a second flexible duct having an inlet and outlet. The second flexible duct inlet is coupled to another of the plenum's openings. The flexible duct outlet is connected through the enclosure's second opening to a second vented duct. The second vented duct has a second vent positioned proximate to a second heat source. A portion of cool air originating from the HVAC system is directed to the second heat source.

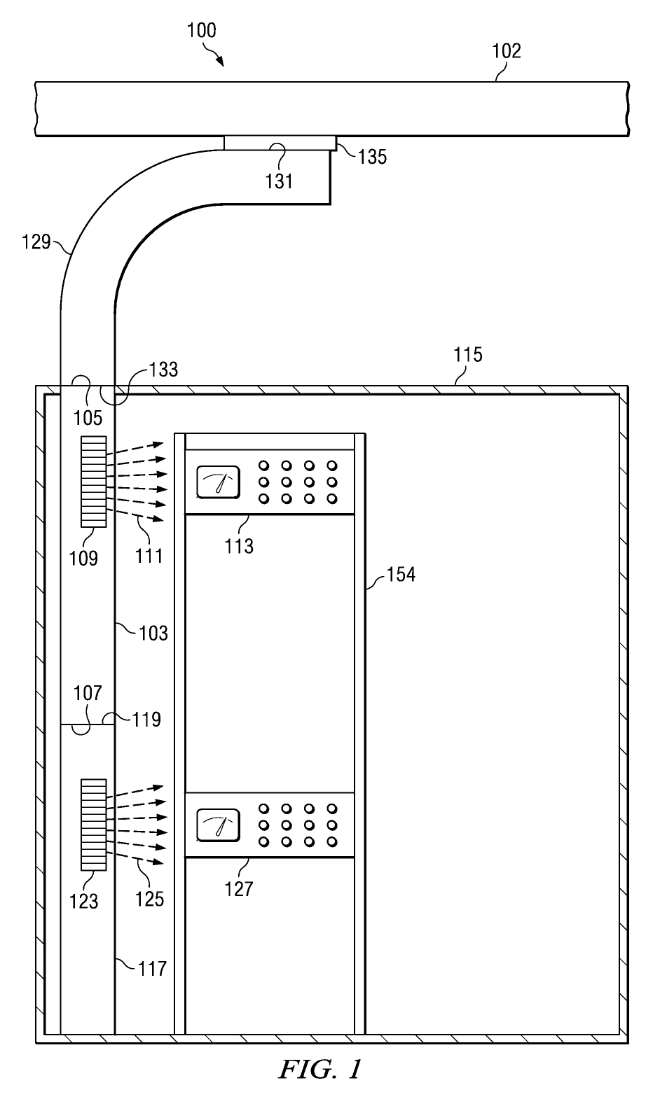

FIG. 1 depicts an embodiment of a direct cooling system 100 that includes a first duct 103. First duct 103 includes a first duct inlet 105, a first duct outlet 107, and a first air output vent 109. First air output vent 109 is positioned to direct first airflow 111 to first heat source 113. First air output vent 109 and first heat source 113 are shown installed within first electronic equipment housing 115.

Direct cooling system 100 also includes first supply duct 129. First supply duct 129 includes first supply duct inlet 131 and first supply duct outlet 133. First supply duct inlet 131 is operatively coupled to HVAC register 135, which is coupled to HVAC supply duct 102. As shown, first supply duct 129 is connected on one end to an HVAC path, which in FIG. 1 includes HVAC register 135. First supply duct outlet 133 is operatively coupled to first duct inlet 105. In the depicted embodiment, first supply duct 129 is exterior to first electronic equipment housing 115 and first duct 103 is internal to first electronic equipment housing 115. As depicted in FIG. 1, first supply duct outlet 133 of first supply duct 129 couples to first duct inlet 105 of first duct 103 through first electronic equipment housing 115.

Cooling system 100, as depicted in FIG. 1, also includes a second duct 11 7. Second duct 117 includes a second duct inlet 119 and a second air output vent 123. Second duct inlet 119 is coupled to first duct outlet 107. As shown, second air output vent 123 is positioned to direct second airflow 125 to second heat source 127. Second heat source 127 is installed with a rack 154. Rack 154, second heat source 127, first heat source 113, and enclosure 115 could be telecommunications equipment in a central office, for example. In some embodiments, any one or more of first supply duct 129, first duct 103, and second duct 117 are made of flexible material, permitting each duct to be flexibly routed in three dimensions. In addition, in some embodiments, first duct 103 and second duct 117 are both made of flexible materials allowing each duct to be extended or shortened from a nominal length. Such flexibility for shortening or extending from a nominal length could be achieved, for example, using metal wire spiraled loosely along an axis and shrouded in an insulating, air tight material. Technology for making such ducts that can be lengthened or shortened is commonly seen, for example, in vents used to carry hot air from residential clothes dryers.

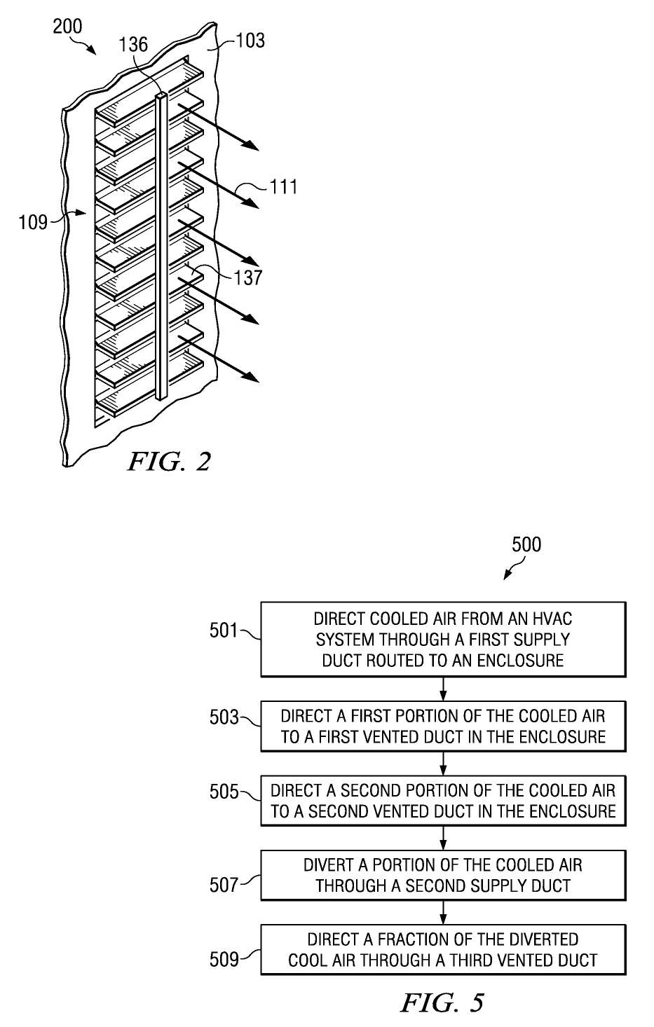

FIG. 2 illustrates a cutaway, enlarged view 200 of first diffuser 137 that, in some embodiments, could be coupled to first air output vent 109. As shown, diffuser 137 acts as a kind of louver, with rod 136 moving up and down, either to increase or decrease air flow. As depicted in FIG. 1, direct cooling system 101 could also include a second diffuser (not shown) coupled to second air output vent 123. In some embodiments, first diffuser 137 is adjustable to restrict variably first airflow 111 and a second diffuser (not shown) is adjustable to restrict variably second airflow 125 (FIG. 1). In addition, in some embodiments, first diffuser 137 is adjustable to change the direction of first airflow 111 and a second diffuser (not shown) is adjustable to change the direction of second airflow 125 (FIG. 1).

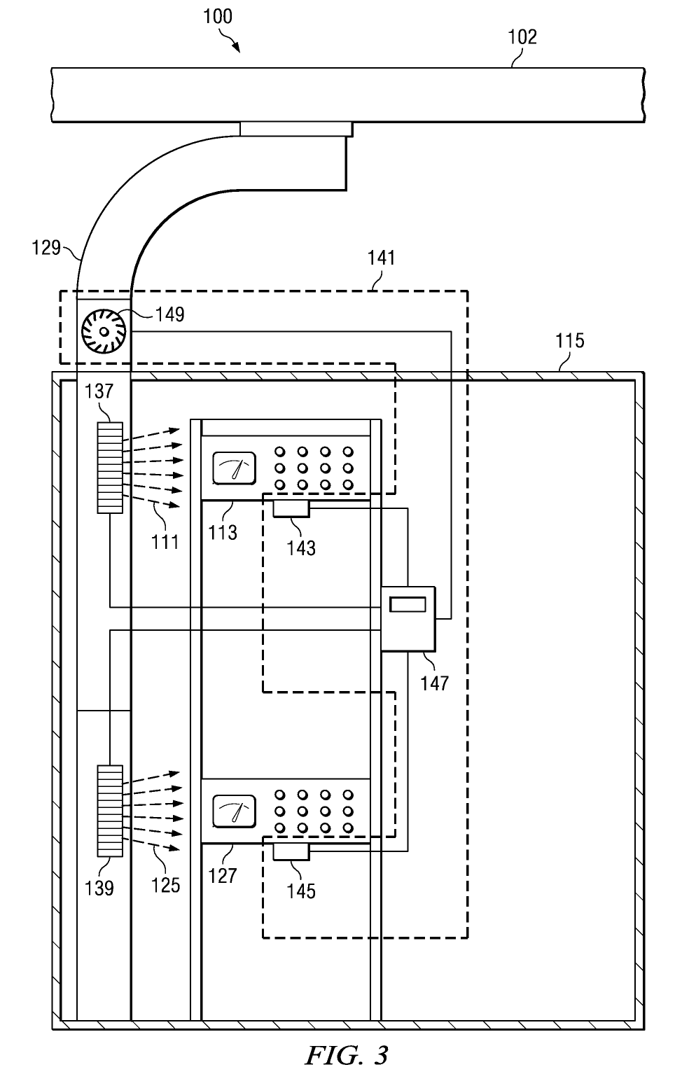

FIG. 3 illustrates an alternate embodiment of direct cooling system 100 including a closed-loop control system 141. As shown, closed-loop control system 141 includes a first temperature sensor 143, a second temperature sensor 145, and a controller 147. In an embodiment, controller 147 monitors signals from first temperature sensor 143 second temperature sensor 145. In response to the monitored signals, controller 147 adjusts first diffuser 137 and second diffuser 139 to achieve proper cooling of first heat source 113 and second heat source 127. To provide such adjustments, diffuser 137 and diffuser 139 could be coupled to electric motors (not shown) responsive to controller 147. Under this scheme, controller 147 could automatically adjust first diffuser 137, thereby affecting first airflow 111 to achieve a desired first temperature of first heat source 113. In addition, controller 147 could automatically adjust second diffuser 139, thereby affecting second airflow 125 to achieve a desired second temperature of second heat source 127.

In an alternate embodiment also incorporated into FIG. 3, direct cooling system 100 optionally includes an electric fan 149 installed in-line with first supply duct 129. Electric fan 149 turns on and off or varies in speed in response to controller 147. Accordingly, flow of cooled air from HVAC supply duct 102 can be increased, thereby providing more air into enclosure 102 through an increase of first airflow 111 and second airflow 125.

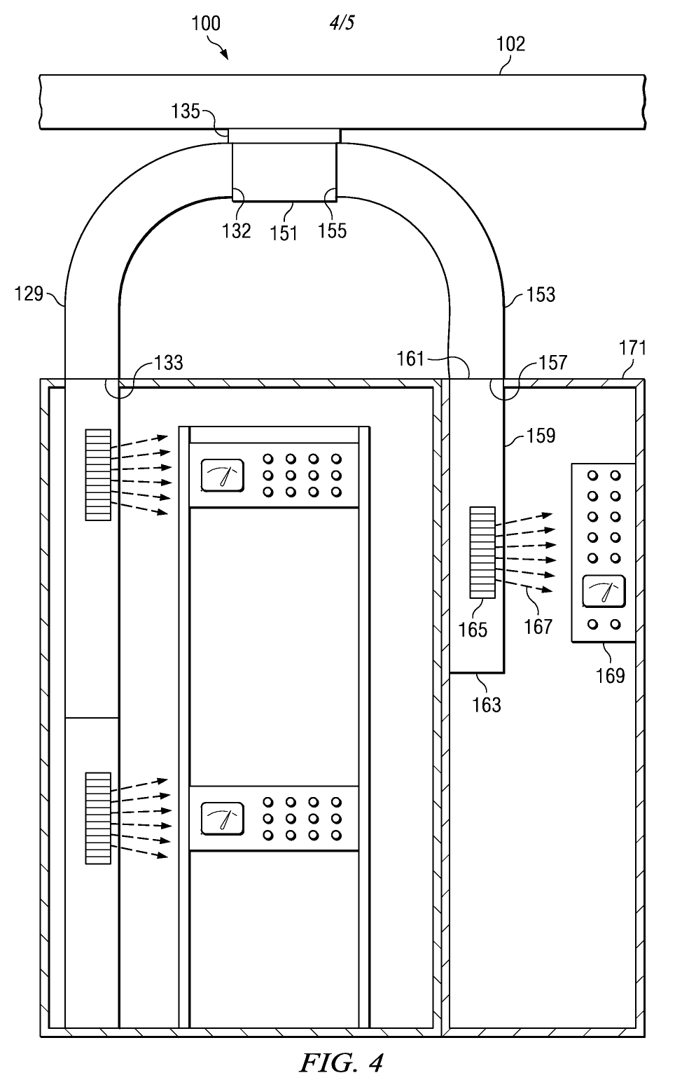

FIG. 4 depicts an alternate embodiment of direct cooling system 100 that includes plenum 151 and second supply duct 153. As shown, HVAC register 135 is coupled to HVAC duct 102. Second supply duct 153 includes a second supply duct inlet 155 and a second supply duct outlet 157. Plenum 151 is operatively coupled to second supply duct inlet 155 and first supply duct inlet 132. First supply duct inlet 132 is from a first supply duct 129, which provides cooled air through first supply duct outlet 133. A third duct 159 includes a third duct inlet 161, a third duct outlet 163, and third air output vent 165. As shown, third duct inlet 161 is operatively coupled to second supply duct outlet 157. Third air output vent 165 is positioned to direct third airflow 167 to third heat source 169. As illustrated, third air output vent 165 and third heat source 169 are installed or positioned within second electronic equipment housing 171. In the embodiment shown in FIG. 4, third duct outlet 163 could be capped-off or otherwise terminated to prevent undesired air flow from the outlet. Alternatively, a fourth duct (not shown) could be added for directing cooled air to another heat source (not shown).

FIG. 5 is a flow diagram illustrating selected blocks of an embodiment of a method 500 for cooling a plurality of electronic components. The embodiment illustrated in FIG. 5 could be implemented using cooling system 100 from FIG. 1, for example. Method 500, as depicted, includes directing (block 501) cooled air from an HVAC system through a first supply duct routed to an enclosure. In an embodiment, the first supply duct is routed from an HVAC register to an enclosure for housing electronic components. Method 500, as shown, further includes directing (block 503) a first portion of the cooled air to a first vented duct within the enclosure. In an embodiment, the first vented duct includes a first vent for directing a fraction of the first portion of the cooled air to a first electronic component. An example electronic component could be any telecommunications module, transformer, or computer system that generates heat and requires cooling. Method 500 further includes directing (block 505) a second portion of the cooled air to a second vented duct within the first enclosure. In an embodiment, the second vented duct includes a second vent for directing a fraction of the cooled air to a second electronic component. Using method 500, better cooling efficiency can be obtained by directing cooled air directly to heat sources within enclosure. In this way, cooled air is applied directly in the vicinity of a heat source, rather than being diffused into the air outside the electrical enclosure after release from a ceiling-mounted HVAC register, for example.

In some embodiments, method 500 may include diverting (block 507) a portion of the cooled air from the HVAC system through a second supply duct. For example as shown in FIG. 4, a second supply duct 153 could be routed from plenum 151, with plenum 151 operatively coupled to HVAC register 135 and first supply duct 129. In such embodiments, the second supply duct could be routed to a second enclosure 171 for cooling of a second heat source 169, which for example, could be one or more electronic components. Method 500 further includes directing (block 509) a fraction of the diverted cool air through a third vented duct to a third heat source. Optionally, equipment used for practicing method 500 would include vents adjustable to restrict the flow of air through the vents. For example, as depicted in FIG. 2, first diffuser 137, which is shown incorporated into first vent 109, could be adjustable to restrict air flow 111.

Alternate embodiments of method 500 could include operating an electric fan to increase cooled air directed from the HVAC system through the first supply duct. For example, for practicing method 500 (FIG. 5) with direct cooling system 100 shown in FIG. 3, electric fan 149 could operate to increase the flow of air through first supply duct 129, thereby increasing the volume of cool air available for cooling heat source 113. Other embodiments of method 500 could include positioning a damper to control an amount of a portion of cooled air from an HVAC system through a second supply duct. For example, for practicing method 500 with system 100 (FIG. 4), plenum 151 could include a damper (not shown) to control the volume of air through second supply duct 153.

In other embodiments, method 500 could include additional elements (not shown) for sensing a first temperature near a first electronic component, sensing a second temperature near a second electronic component, and automatically increasing airflow to the first electronic component to lower the temperature of the first electronic component. These additional elements could be performed by cooling system 100 as shown in FIG. 3. For example, as shown in FIG. 3, closed-loop control system 141, including controller 147, could monitor signals (not shown) from first temperature sensor 143 and from second temperature sensor 145. Controller 147 could automatically adjust first diffuser 137 to increase first airflow 111 to achieve a lower temperature near first heat source 113. In this way, method 500 could include elements for automatically monitoring and decreasing the temperature of one or more electronic components within an equipment housing. Such a method using a closed-loop control system would provide for a more robust control scheme compared to an open loop system, which might only output a steady amount of airflow near heat sources without monitoring the effects of the airflow on the heat sources, thereby resulting in unbalanced or otherwise ineffective cooling.

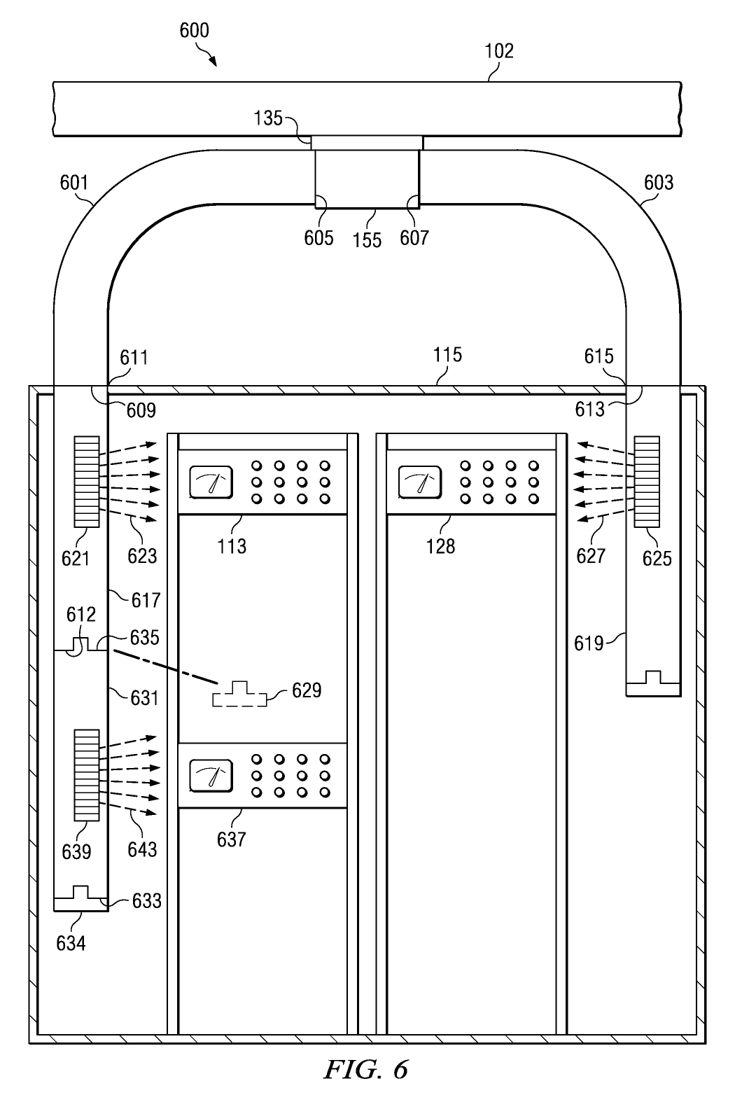

FIG. 6 illustrates an embodied cooling system 600 for retrofitting to an existing HVAC system including HVAC supply duct 102 and HVAC register 135. HVAC supply duct 102 and HVAC register 135, for purposes of illustrating the current embodiment, could be the same HVAC components illustrated in FIGS. 1 and 4. Cooling system 600 includes plenum 155 coupled to HVAC register 135. Plenum 155 has a plurality of openings, with one opening coupled to first flexible duct 601 and another opening coupled to second flexible duct 603. More specifically, plenum 155's first opening is coupled to a first flexible duct inlet 605 and plenum 155's second opening is coupled to a second flexible duct inlet 607. First flexible duct outlet 609 is coupled through enclosure 115's first opening 611 to first vented duct 617. First vented duct 617 has a first vent 621 positioned proximate to first heat source 113 for directing a portion of cool air 623 from the HVAC system to first heat source 113.

Similarly, as depicted in FIG. 6, second flexible duct outlet 603 is coupled through enclosure 115's second opening 615 to second vented duct 619. Second vented duct 619 has vent 625 positioned proximate to second heat source 128 for directing a second portion of cooled air 627 originating from the HVAC system to second heat source 128. In this way, cooling system 600 provides an efficient system of directly cooling first heat source 113 and second heat source 128. This would be especially useful if first heat source 113 and second heat source 128 were high-heat devices. In other words, if these heat sources typically produced a large amount of heat compared to other devices (not shown) inside enclosure 115, cooling system 600 would provide an efficient system for cooling these high-heat devices due to cool air directed in close proximity to the high heat devices.

First vented duct 617 includes first vented duct outlet 612. In some embodiments, first vented duct outlet 612 is adapted to receive first baffle 629 or third flexible duct 631. Accordingly, first baffle 629 could be installed into first vented duct outlet 612 if other flexible duct were not required, or if it were otherwise necessary to prevent airflow from the end of first vented duct outlet 612. As shown in FIG. 6, because a third high-heat source 637 is present in enclosure 115, a third flexible duct 631 could be coupled to first vented duct 617 by connecting first vented duct outlet 612 to second vented duct inlet 635. Third flexible duct 631 includes a third vent 639 positioned proximate to third heat source 637 within enclosure 115. Third vent 639 is positioned to direct a third portion of cool air 643 from the HVAC system to third heat source 637.

Therefore, because of third high heat source 637 in enclosure 115, first baffle 629 is not installed. This allows third flexible duct 631 to be coupled to flexible duct outlet 612 to further distribute air from the HVAC system. If third high heat source 637 were removed from enclosure 115, then third flexible duct 631 could be removed and first baffle 629 could be installed, to prevent leakage of any air from the end of first vented duct 617.

As shown in FIG. 6, third flexible duct 631 has an outlet 633 and an inlet 635. Third flexible duct outlet 633, similar to first flexible duct outlet 612, is adaptable to receive a second baffle 634 or a fourth flexible duct inlet (not shown). Having flexible ducts with outlets alternately adaptable to receive baffles and other flexible ducts allows for flexibility in configuring cooling ducts within enclosure 115. If high heat sources were added to enclosure 115, the baffle could be removed from the end of the last flexible duct, and additional flexible ducts could be added. In this way, cooling system 600 in FIG. 6 is easily expanded or otherwise reconfigured to take into account changes in the types of equipment installed. In alternate embodiments of the cooling system shown in FIG. 6, first vent 621, second vent 625, and third vent 639 could each be independently adjustable to restrict airflow. This independent adjustment could be accomplished in a variety of ways, including as illustrated in FIG. 2.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the presently claimed subject matter is to be determined by the broadest permissible interpretation of the following claims and their equivalents, and shall not be restricted or limited by the foregoing detailed description.

What is claimed is:

1. A directly cooled system comprising:
a first supply duct having a first end and a second end, the first supply duct's first end connectable to an HVAC path; and
a first duct, the first duct including an inlet, an outlet, and a first air output vent, the first air output vent positioned to direct a first airflow to a first heat source, the first air output vent and a first heat source positioned within a first electronic equipment housing, the first duct inlet connectable through the first electronic equipment housing to the first supply duct's second end.

2. The directly cooled system of claim 1, further comprising:
a second duct, the second duct including an inlet and a second air output vent, the second duct inlet coupled to the first duct outlet, the second air output vent positioned to direct a second airflow to a second heat source positioned within the first electronic equipment housing.

3. The directly cooled system of claim 2, further comprising:
a first diffuser coupled to the first air output vent, the first diffuser adjustable to variably restrict the first airflow; and
a second diffuser coupled to the second air output vent, the second diffuser adjustable to variably restrict the second airflow.

4. The directly cooled system of claim 2, wherein the first diffuser is adjustable to change the direction of the first airflow, wherein the second diffuser is adjustable to change the direction of the second airflow.

5. The directly cooled system of claim 1, wherein the first supply duct, the first duct, and the second duct are made of flexible material permitting each duct to be flexibly routed in three dimensions.

6. The directly cooled system of claim 5, wherein the first duct and the second duct are made of flexible material allowing each duct to be extended and shortened from a nominal length.

7. The directly cooled system of claim 2, wherein the second duct outlet is adapted to receive a baffle, wherein the second duct outlet is adapted to receive a third duct inlet.

8. The directly cooled system of claim 3, further comprising:
a closed-loop control system, the closed-loop control system comprising:
a first temperature sensor positioned to monitor a first temperature of the first heat source;
a second temperature sensor positioned to monitor a second temperature of the second heat source; and
a controller, the controller for automatically adjusting the first diffuser to affect the first airflow to achieve a desired first temperature, the controller for automatically adjusting the second diffuser to affect the second airflow to achieve a desired second temperature.

9. The directly cooled system of claim 3, further comprising:
an electric fan, the electric fan installed in-line with the first supply duct to increase the first airflow and the second airflow, wherein the electric fan has a running speed responsive to the controller.

10. The directly cooled system of claim 1, further comprising:
a second supply duct having a first end and a second end, the second supply duct first end connectable to the HVAC path; and
a third duct, the third duct including an inlet, an outlet, and a third air output vent, wherein the third duct inlet is connectable to the second supply duct second end, the third air output vent positioned to direct a third airflow to a third heat source, wherein the third air output vent and the third heat source are installed within a second electronic equipment housing.

11. A method of enabling direct cooling of a plurality of electronic components using a volume of cooled air directed from an HVAC system through a first supply duct, the first supply duct routed from an HVAC register to a first enclosure, the first enclosure for housing a first portion of the electronic components, the method comprising:
enabling a first vented duct within the first enclosure to emit a first portion of the volume of cooled air toward a first electronic component.

12. The method of claim 11, the method further comprising the step of:
enabling a second vented duct within the first enclosure to emit a second portion of the volume of cooled air toward a second electronic component.

13. The method of claim 11, the method further for using a diverted portion of the cooled air from the HVAC system through a second supply duct, the second supply duct and the first supply duct routed from a plenum attached to the HVAC register, the second supply duct routed to a second enclosure, the second enclosure for housing a second portion of the electronic components, the method further comprising:
enabling a third vented duct within the second enclosure to direct a fraction of the diverted cooled air toward a third electronic component.

14. The method of claim 12, wherein the first vented duct includes a first vent, wherein the second vented duct includes a second vent, the first vent adjustable to reduce the first portion of the volume of cooled air, the second vent adjustable to reduce the second portion of the volume of cooled air.

15. The method of claim 11, the method further comprising the step of:
operating an electric fan to increase the volume of cooled air directed from the HVAC system through the first supply duct.

16. The method of claim 12, the method further comprising the steps of:
sensing a first temperature near the first electronic component;
sensing a second temperature near the second electronic component;
automatically increasing the first fraction of the first portion of the volume of cooled air to lower the first temperature.

17. A cooling system for retrofitting to an existing heating, ventilating, and air conditioning (HVAC) system, the HVAC system including an HVAC supply duct, an HVAC register, and a plenum having at least two openings, the cooling system comprising:
a first flexible duct having an inlet and outlet, the first flexible duct inlet coupled to a first of the plenum's openings, the first flexible duct outlet connected through an enclosure's first opening to a first vented duct, the first vented duct having a first vent positioned proximate to a first heat source for directing a first portion of cool air originating from the HVAC system to the first heat source; and
a second flexible duct having an inlet and outlet, the second flexible duct's inlet coupled to a second of the plenum's openings, the second flexible duct outlet connected through an enclosure's second opening to a second vented duct, the second vented duct having a second vent positioned proximate to a second heat source for directing a second portion of cool air originating from the HVAC system to the second heat source.

18. The cooling system of claim 17, wherein the first vented duct has an outlet adapted to receive:
a first baffle for preventing airflow through the first vented duct outlet; and
a third vented duct having an inlet and an outlet, wherein the third vented duct outlet is adapted to receive a second baffle and a fourth vented duct inlet.

19. The cooling system of claim 18, wherein the second vented duct has an outlet configured to receive:
a third baffle for preventing airflow through the second vented duct outlet; and
a fifth flexible duct having an inlet and outlet, wherein the fifth flexible duct outlet is configured to alternately receive a fourth baffle and a sixth vented duct inlet.

20. The cooling system of claim 18, wherein the third vented duct inlet is coupled to the second vented duct outlet, wherein the third vented duct has a third vent positioned proximate to a third heat source within an enclosure to direct a third portion of cool air originating from the HVAC system to the third heat source, wherein each of the first, second, and third vents is independently adjustable to restrict air flow through itself.
